(19) United States
(12) Patent Application Publication
(10) Pub. No.: US 2025/0372537 A1
(43) Pub. Date: Dec. 4, 2025

(54) SEMICONDUCTOR PACKAGE

(71) Applicant: Samsung Electronics Co., Ltd., Suwon-si (KR)

(72) Inventors: Sunkyoung Seo, Suwon-si (KR); Daewoo Kim, Suwon-si (KR); Yonghoe Cho, Suwon-si (KR); Chajea Jo, Suwon-si (KR)

(21) Appl. No.: 19/024,894

(22) Filed: Jan. 16, 2025

(30) Foreign Application Priority Data
May 31, 2024 (KR) 10-2024-0071789

(51) Int. Cl. H01L 23/00; H01L 23/31; H01L 23/373; H01L 25/03

(52) U.S. Cl. CPC H01L 23/562; H01L 23/3135; H01L 23/3735; H01L 25/03; H01L 2225/06541

(57) ABSTRACT

A semiconductor package includes a semiconductor chip including a plurality of through vias, a plurality of stacked structures located on a top surface of the semiconductor chip and including a plurality of core chips stacked in a vertical direction, the plurality of stacked structures spaced apart from one another in a horizontal direction, a stiffener located on the plurality of stacked structures, a first adhesive layer located on a bottom surface of the stiffener and including a top surface having the same area as a bottom surface of the stiffener, and a molding layer located on a top surface of the semiconductor chip and surrounding the plurality of stacked structures, the stiffener, and the first adhesive layer. A thermal expansion coefficient of the stiffener is the same as that of the semiconductor chip, and an uppermost surface of the molding layer is coplanar with a top surface of the stiffener.

### CROSS-REFERENCE TO RELATED APPLICATION

This application is based on and claims priority under 35 U.S.C. § 119 to Korean Patent Application No. 10-2024-0071789, filed on May 31, 2024, in the Korean Intellectual Property Office, the disclosure of which is incorporated by reference herein in its entirety.

### BACKGROUND

The inventive concept relates to a semiconductor package, and more particularly, to a semiconductor package including a plurality of stacked structures.

Recently, in accordance with the rapid development of the electronics industry and user demand, electronic devices have become more miniaturized, multifunctional, and large-capacity, requiring highly integrated semiconductor chips. Therefore, a semiconductor package including a highly integrated semiconductor chip with an increased number of connection terminals for input/output (I/O) while ensuring connection reliability is being designed.

### SUMMARY

Aspects of the inventive concept relate to a semiconductor package in which a warpage phenomenon is suppressed.

Issues addressed by the technical idea of the inventive concept are not limited to the above-mentioned issues, and other issues not mentioned will be clearly understood by those skilled in the art from the following description.

According to an aspect of the inventive concept, there is provided a semiconductor package including a semiconductor chip including a plurality of through vias, a plurality of stacked structures located on a top surface of the semiconductor chip, each of the plurality of stacked structures including a plurality of core chips stacked in a vertical direction, the plurality of stacked structures spaced apart from one another in a horizontal direction, a stiffener located on the plurality of stacked structures, a first adhesive layer located on a bottom surface of the stiffener and including a top surface having the same area as a bottom surface of the stiffener, and a molding layer located on a top surface of the semiconductor chip and surrounding the plurality of stacked structures, the stiffener, and the first adhesive layer. A thermal expansion coefficient of the stiffener is the same as that of the semiconductor chip, and an uppermost surface of the molding layer is coplanar with a top surface of the stiffener.

According to another aspect of the inventive concept, there is provided a semiconductor package including an interposer, a semiconductor chip located on the interposer, a plurality of stacked structures located on the interposer, spaced apart from the semiconductor chip in a horizontal direction, and each stacked structure including a plurality of core chips stacked in a vertical direction, a first stiffener located on the semiconductor chip and the plurality of stacked structures, a first adhesive layer located on a bottom surface of the first stiffener and including a top surface having the same area as a bottom surface of the first stiffener, and a molding layer located on the interposer and surrounding the semiconductor chip, the plurality of stacked structures, the first stiffener, and the first adhesive layer, wherein the first stiffener covers a first portion of the molding layer located in a space between the plurality of stacked structures and a space between each of the plurality of stacked structures and the semiconductor chip, and wherein an uppermost surface of the first stiffener is coplanar with a top surface of the molding layer.

According to another aspect of the inventive concept, there is provided a semiconductor package including a package board, a semiconductor chip located on the package board and including a plurality of through vias, a plurality of stacked structures located on a top surface of the semiconductor chip, each stacked structure including a plurality of core chips stacked in a vertical direction, and the plurality of stacked structures spaced apart from one another in a horizontal direction, a stiffener located on the plurality of stacked structures, a first adhesive layer located on a bottom surface of the stiffener and including a top surface having the same area as a bottom surface of the stiffener, a molding layer located on a top surface of the semiconductor chip and surrounding the plurality of stacked structures, the stiffener, and the first adhesive layer, and a heat dissipation layer located on the stiffener and having a top surface wider than a top surface of the semiconductor chip, wherein the stiffener covers a first portion of the molding layer located in a space between the plurality of stacked structures. A thermal expansion coefficient of the stiffener is the same as that of the semiconductor chip. An uppermost surface of the molding layer is coplanar with a top surface of the stiffener. Side surfaces of the molding layer are respectively coplanar with corresponding side surfaces of the semiconductor chip.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor package according to an embodiment;

FIG. 2 is a cross-sectional view schematically illustrating the semiconductor package of FIG. 1 taken along line A1-A1′ in FIG. 1;

FIG. 3 is a cross-sectional view schematically illustrating a semiconductor package according to an embodiment;

FIG. 4 is a cross-sectional view schematically illustrating a semiconductor package according to an embodiment;

FIG. 5 is a cross-sectional view schematically illustrating a semiconductor package according to an embodiment;

FIG. 6 is a plan view schematically illustrating a semiconductor package according to an embodiment;

FIG. 7 is a cross-sectional view schematically illustrating the semiconductor package of FIG. 6 taken along line A2-A2′ in FIG. 6;

FIG. 8 is a plan view schematically illustrating a semiconductor package according to an embodiment;

FIG. 9 is a cross-sectional view schematically illustrating the semiconductor package of FIG. 8 taken along line B1-B1′ in FIG. 8;

FIG. 10 is a cross-sectional view schematically illustrating a semiconductor package according to an embodiment;

FIG. 11 is a plan view schematically illustrating a semiconductor package according to an embodiment;

FIG. 12 is a cross-sectional view schematically illustrating the semiconductor package of FIG. 11 taken along line B2-B2′ in FIG. 11;

FIG. 13 is a cross-sectional view schematically illustrating a semiconductor package according to an embodiment; and

FIG. 14 is a cross-sectional view schematically illustrating a semiconductor package according to an embodiment.

### DETAILED DESCRIPTION OF THE EMBODIMENTS

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

As used herein, components described as being “electrically connected” are configured such that an electrical signal can be transferred from one component to the other (although such electrical signal may be attenuated in strength as it is transferred and may be selectively transferred).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Spatially relative terms, such as “beneath,” “below,” “lower,” “above,” “upper,” “top,” “bottom,” “front,” “rear,” “vertical,” “horizontal,” and the like, may be used herein for ease of description to describe positional relationships, such as illustrated in the figures, for example. It will be understood that the spatially relative terms encompass different orientations of the device in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Because embodiments may be subject to various changes and have various forms, some embodiments will be illustrated in the drawings and described in detail. However, this is not intended to limit the embodiments to a specific disclosure form.

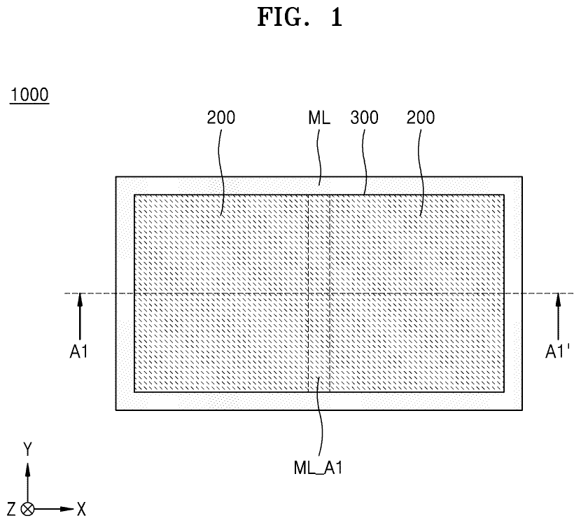

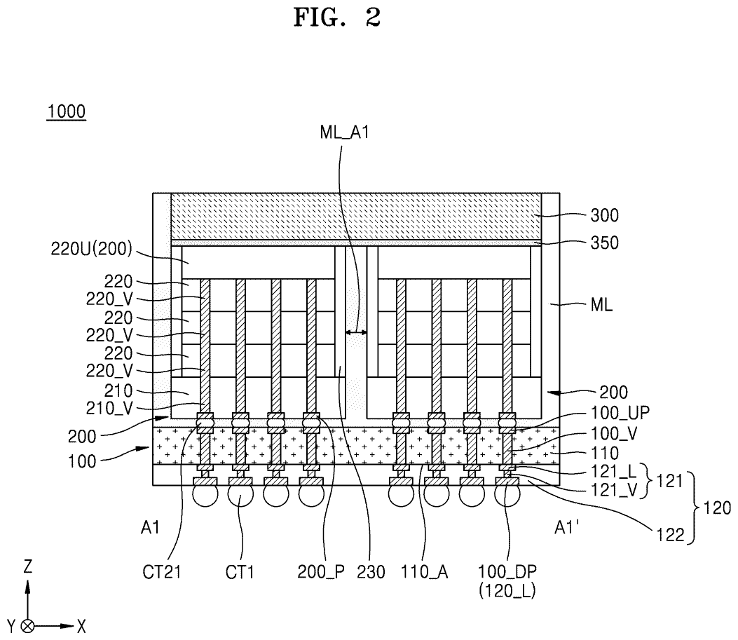

FIG. 1 is a plan view schematically illustrating a semiconductor package 1000 according to an embodiment. FIG. 2 is a cross-sectional view schematically illustrating the semiconductor package 1000 of FIG. 1 taken along line A1-A1′ of FIG. 1.

Referring to FIGS. 1 and 2, the semiconductor package 1000 may include a semiconductor chip 100, a plurality of stacked structures 200, a stiffener 300, a first adhesive layer 350, and a molding layer ML.

Hereinafter, unless specifically defined, a direction parallel to a top surface of the stiffener 300 is defined as a first horizontal direction (X direction), a direction perpendicular to the top surface of the stiffener 300 is defined as a vertical direction (Z direction), and a direction perpendicular to the first horizontal direction (X direction) and the vertical direction (Z direction) is defined as a second horizontal direction (Y direction). A horizontal direction is defined as a direction obtained by combining the first horizontal direction (X direction) with the second horizontal direction (Y direction). For example, a horizontal direction may be any direction perpendicular to the vertical direction.

The semiconductor chip 100 may include a first substrate 110, a first wiring structure 120, and a plurality of first through vias 100_V. The first substrate 110 may include an active surface 110_A on which a plurality of individual devices are formed and an inactive surface opposing the active surface 110_A. The first wiring structure 120 may be formed on the active surface 110_A of the first substrate 110. The plurality of first through vias 100_V may extend from the inactive surface of the first substrate 110 to the active surface 110_A. In some embodiments, the plurality of first through vias 100_V may be electrically connected to the plurality of individual devices on the first wiring structure 120 and/or the active surface 110_A.

In some embodiments, the first substrate 110 may include a semiconductor material such as silicon (Si). Alternatively, the first substrate 110 may include a semiconductor material such as germanium (Ge).

In some embodiments, a plurality of various types of individual devices may be located on the active surface 110_A of the first substrate 110. For example, the plurality of individual devices may include various micro-electronic devices, for example, a complementary metal-oxide semiconductor (CMOS) transistor, a metal-oxide-semiconductor field effect transistor (MOSFET), system large scale integration (LSI), an image sensor such as a CMOS imaging sensor (CIS), a micro-electro-mechanical system (MEMS), an active device, and a passive device.

In some embodiments, the semiconductor chip 100 may include an application specific integrated circuit (ASIC). For example, the semiconductor chip 100 may be a logic die.

The semiconductor chip 100 may be located under the plurality of stacked structures 200 such that the active surface 110_A of the first substrate 110 is apart from (e.g., opposite) the plurality of stacked structures 200. For example, the active surface 110_A of the first substrate 110 may face downward in the vertical direction (Z direction). For example, the semiconductor chip 100 may be arranged in a face down manner.

However, the inventive concept is not limited thereto, and the semiconductor chip 100 may be located under the plurality of stacked structures 200 such that the active surface 110_A of the first substrate 110 faces the plurality of stacked structures 200 in certain embodiments. For example, the semiconductor chip 100 may be arranged in a face up manner.

The first wiring structure 120 may include first wiring patterns 121 and a first wiring insulating layer 122 surrounding the first wiring patterns 121. The first wiring patterns 121 may include first wiring lines 121_L extending in a horizontal direction and first wiring vias 121_V extending in the vertical direction (Z direction) from the first wiring lines 121_L. The first wiring patterns 121 may be electrically connected to first through vias 100_V.

For example, the first wiring insulating layer 122 may include silicon oxide, silicon nitride, silicon oxynitride, an insulating material with a lower dielectric constant than silicon oxide, or a combination thereof.

The semiconductor chip 100 may further include upper pads 100_UP and lower pads 100_DP. The lower pads 100_DP may be located on the first wiring structure 120 and may be electrically connected to the first wiring patterns 121 of the first wiring structure 120. In some embodiments, the lower pads 100_DP may be externally exposed portions of the first wiring patterns 121.

The upper pads 100_UP of the semiconductor chip 100 may be located on the inactive surface of the first substrate 110. For example, the lower pads 100_DP may be located on a bottom surface of the semiconductor chip 100, and the upper pads 100_UP may be located on a top surface of the semiconductor chip 100. For example, the plurality of first through vias 100_V may electrically connect the upper pads 100_UP to the lower pads 100_DP, respectively.

External connection terminals CT1 may be attached to the lower pads 100_DP of the semiconductor chip 100. The external connection terminals CT1 may electrically and physically connect the semiconductor chip 100 to an external device on which the semiconductor chip 100 is mounted. The external connection terminals CT1 may include, for example, solder balls or solder bumps.

The plurality of stacked structures 200 may be located on the top surface of the semiconductor chip 100. The plurality of stacked structures 200 may be spaced apart from one another in a horizontal direction. Although it is illustrated in FIG. 1 that two stacked structures 200 are arranged on the semiconductor chip 100, the number of stacked structures 200 is not limited thereto.

Each of the plurality of stacked structures 200 may include a buffer chip 210, a plurality of core chips 220, and a core molding layer 230. The buffer chip 210 of each of the plurality of stacked structures 200 may be located at the lowermost end (e.g., under the lowest core chip 220 among the plurality of core chips 220) of each of the plurality of stacked structures 200, and the plurality of core chips 220 may be stacked on the buffer chip 210 in the vertical direction (Z direction). The core molding layer 230 may be located on the buffer chip 210 and may surround the plurality of core chips 220. For example, the core molding layer 230 may surround/contact side surfaces of the plurality of core chips 220.

For example, a top surface of the core molding layer 230 may be coplanar with a top surface of the uppermost core chip 220U. Accordingly, the top surface of the uppermost core chip 220U may contact the first adhesive layer 350.

Each of the buffer chip 210 and the plurality of core chips 220 may include, for example, a semiconductor material such as Si or Ge. Each of the buffer chip 210 and the plurality of core chips 220 may include a compound semiconductor material such as silicon carbide (SiC), gallium arsenide (GaAs), indium arsenide (InAs), or indium phosphide (InP).

Each of the buffer chip 210 and the plurality of core chips 220 may include an active surface and an inactive surface opposing the active surface. A semiconductor device including one or more of the plurality of various types of individual devices may be formed on the active surface of each of the buffer chip 210 and the plurality of core chips 220. Each of the buffer chip 210 and the plurality of core chips 220 may include a well doped with impurities as a wiring region. Each of the buffer chip 210 and the plurality of core chips 220 may have various device isolation structures such as a shallow trench isolation (STI) structure.

The plurality of individual devices of the buffer chip 210 may include various micro-electronic devices, for example, a MOSFET such as a CMOS transistor, a system LSI, an image sensor such as a CIS, a MEMS, an active device, and a passive device.

The plurality of individual devices of each of the plurality of core chips 220 may include a memory cell. For example, the memory cell may include a non-volatile memory cell such as flash memory, phase-change random access memory (PRAM), magnetoresistive random access memory (MRAM), ferroelectric random access memory (FeRAM), or resistive random access memory (RRAM). In some embodiments, the memory cell may include a volatile memory cell such as dynamic random access memory (DRAM) or static random access memory (SRAM).

The plurality of individual devices of the buffer chip 210 may be electrically connected to the wiring region of the buffer chip 210, and the plurality of individual devices of each of the plurality of core chips 220 may be electrically connected to the wiring region of each of the plurality of core chips 220.

In some embodiments, the buffer chip 210 may include a serial-parallel conversion circuit and may be a semiconductor chip for controlling the plurality of core chips 220, and each of the plurality of core chips 220 may be a memory chip including memory cells.

For example, each of the plurality of stacked structures 200 may be high bandwidth memory (HBM), the buffer chip 210 may be an HBM controller die, and each of the plurality of core chips 220 may a DRAM die.

In some embodiments, a core chip located at the uppermost end of the plurality of core chips 220 may be referred to as the uppermost core chip 220U. Although it is illustrated in FIG. 2 that four core chips 220 are stacked in each of the plurality of stacked structures 200, the number of core chips 220 included in the plurality of stacked structures 200 is not limited thereto.

In some embodiments, core chips excluding the uppermost core chip 220U among the plurality of core chips 220 may further include core through vias 220_V extending inward from top surfaces of the core chips, e.g., through the core chips in a thickness direction to respective bottom surfaces of the core chips. The core through vias 220_V of each of the plurality of core chips 220 may be electrically connected to the wiring region of each of the plurality of core chips 220.

Each of the plurality of core chips 220 may be electrically connected to a neighboring core chip or the buffer chip 210 through the core through vias 220_V. Accordingly, each of the plurality of core chips 220 may be electrically connected to the semiconductor chip 100 through the core through vias 220_V. For example, the wiring region of the uppermost core chip 220U may be electrically connected to the semiconductor chip 100 through the core through vias 220_V of the core chips stacked under the uppermost core chip 220U.

In some embodiments, a thickness of each of the plurality of core chips 220, that is, a length of each of the plurality of core chips 220 in the vertical direction (Z direction) may be about 20 um to about 80 um. The thicknesses of the plurality of core chips 220 may have substantially the same value. For example, a thickness of the uppermost core chip 220U among the plurality of core chips 220 may be substantially the same as a thickness of another core chip 220.

In some embodiments, lower pads 200_P may be located on a bottom surface of the buffer chip 210. The lower pads 200_P of the buffer chip 210 may be electrically connected to the wiring region of the buffer chip 210 and buffer through vias 210_V of the buffer chip 210.

The lower pads 200_P of the buffer chip 210 may be electrically connected to the semiconductor chip 100 by first connection terminals CT21. However, the inventive concept is not limited thereto, and the lower pads 200_P of the buffer chip 210 may be electrically connected to the semiconductor chip 100 by an anisotropic film (ACF), a non-conductive film (NCF), direct bonding, or hybrid bonding.

The stiffener 300 may be located on the plurality of stacked structures 200. In some embodiments, the stiffener 300 may have a flat plate shape. For example, the stiffener 300 may be a flat plate, e.g., a rectangular plate. For example, a thermal expansion coefficient of the stiffener 300 may be substantially the same as that of the semiconductor chip 100. For example, a constituent material of the stiffener 300 may be substantially the same as that of the first substrate 110 of the semiconductor chip 100. For example, the stiffener 300 may include the same semiconductor material as the first substrate 110 of the semiconductor chip 100. For example, the stiffener 300 may include Si.

The first adhesive layer 350 may be located on a bottom surface of the stiffener 300. The area of a top surface of the first adhesive layer 350 may be the same as that of the bottom surface of the stiffener 300. For example, side surfaces of the first adhesive layer 350 may be respectively coplanar with corresponding side surfaces of the stiffener 300. For example, in a process of attaching the stiffener 300 onto the plurality of stacked structures 200, after attaching the first adhesive layer 350 to the bottom surface of the stiffener 300, the stiffener 300 may be attached onto the plurality of stacked structures 200 through the first adhesive layer 350.

In some embodiments, the first adhesive layer 350 may include an adhesive film such as an NCF or a die attach film (DAF).

In some embodiments, the first adhesive layer 350 may include silicon oxide. For example, the stiffener 300 may further include an oxide layer located on the bottom surface of the stiffener 300, and each of the plurality of stacked structures 200 may further include an oxide layer located on the top surface of the uppermost core chip 220U. The first adhesive layer 350 may be formed by diffusion bonding the oxide layer of the stiffener 300 with the oxide layer of each of the plurality of stacked structures 200 by heat. For example, the first adhesive layer 350 may refer to the oxide layer of the stiffener 300 and the oxide layer of each of the plurality of stacked structures 200, which are integrated by diffusion bonding. In some embodiments, the stiffener 300 may be attached onto the plurality of stacked structures 200 through direct bonding. For example, the direct bonding may be a bonding between the stiffener 300 and the plurality of stacked structures 200 in which the stiffener 300 and the uppermost core chips 220U of the plurality of stacked structures 200 are attached without any additional intermediate layers, e.g., without the additional adhesive layer 350 between the stiffener 300 and the uppermost core chips 220U.

The molding layer ML may be located on the semiconductor chip 100. The molding layer ML may surround the plurality of stacked structures 200, the first adhesive layer 350, and the stiffener 300. The uppermost surface of the molding layer ML may be coplanar with the top surface of the stiffener 300. For example, the molding layer ML may contact the top surface of the semiconductor chip 100, side surfaces of each of the plurality of stacked structures 200, a bottom surface and the side surfaces of the first adhesive layer 350, and the side surfaces of the stiffener 300.

A thermal expansion coefficient of the molding layer ML located on the semiconductor chip 100 may be different from that of the semiconductor chip 100. According to the inventive concept, the plurality of stacked structures 200 are mounted on one semiconductor chip 100 so that volumes of the semiconductor chip 100 and the molding layer ML may be increased. For example, the volume of the semiconductor package 1000 may be relatively large compared to a semiconductor package including a single stacked structure or including a smaller number of stacked chips. The molding layer ML may be relatively thick when the plurality of stacked structures 200 are mounted on the semiconductor chip 100 and the molding layer ML covers the plurality of stacked structures 200 compared to a molding layer formed on a single stacked structure or a smaller number of stacked chips. In general, when the volumes of the semiconductor chip 100 and the molding layer ML increase, a warpage phenomenon, in which the semiconductor chip 100 and the molding layer ML are convexly or concavely bent due to a difference in thermal expansion coefficient between the semiconductor chip 100 and the molding layer ML, may occur. The semiconductor package 1000 according to the inventive concept may include the stiffener 300 of which thermal expansion coefficient is substantially the same as that of the semiconductor chip 100. Because the volume and area of the molding layer ML are reduced by the stiffener 300, a warpage phenomenon of the semiconductor chip 100 may be suppressed. For example, attaching the stiffener 300 on the molding layer ML and the plurality of stacked structures 200 may be helpful for reducing the volume of the molding layer ML, e.g., by reducing/removing an upper portion of the molding layer ML where the stiffener 300 is placed.

The molding layer ML may be located in a horizontal space (e.g., a gap in a horizontal direction) between adjacent stacked structures of the plurality of stacked structures 200. For example, the molding layer ML may fill the horizontal space between adjacent stacked structures of the plurality of stacked structures 200. A portion of the molding layer ML located in a space between adjacent stacked structures of the plurality of stacked structures 200 may be referred to as a first portion ML_A1 of the molding layer ML.

In some embodiments, the molding layer ML may include epoxy resin or polyimide resin. The molding layer ML may include, for example, an epoxy molding compound (EMC).

Part of the stiffener 300 may be located on the first portion ML_A1 of the molding layer ML. For example, the stiffener 300 may be located on the space between adjacent stacked structures of the plurality of stacked structures 200. Part of the first adhesive layer 350 may contact a top surface of the first portion ML_A1 of the molding layer ML. For example, part of the first adhesive layer 350 may be between the first portion ML_A1 of the molding layer ML and the stiffener 300.

In some embodiments, the stiffener 300 may completely cover a top surface of each of the plurality of stacked structures 200 and the first portion ML_A1 of the molding layer ML. For example, the area of the stiffener 300 (e.g., the area from a plan view, for example, of the bottom or top surface of the stiffener 300) may be equal to the sum of the areas of the top surfaces of the plurality of stacked structures 200 and the area of the top surface of the first portion ML_A1 of the molding layer ML. For example, the side surfaces of the stiffener 300 may be respectively coplanar with corresponding side surfaces of the outermost stacked structure among the plurality of stacked structures 200.

In the semiconductor package 1000 according to the inventive concept, a warpage phenomenon of the semiconductor chip 100 may be suppressed by the stiffener 300 located on the space between two adjacent stacked structures the plurality of stacked structures 200. For example, the stiffener 300 may prevent the plurality of stacked structures 200 from being tilted/bent by the first portion ML_A1 of the molding layer ML.

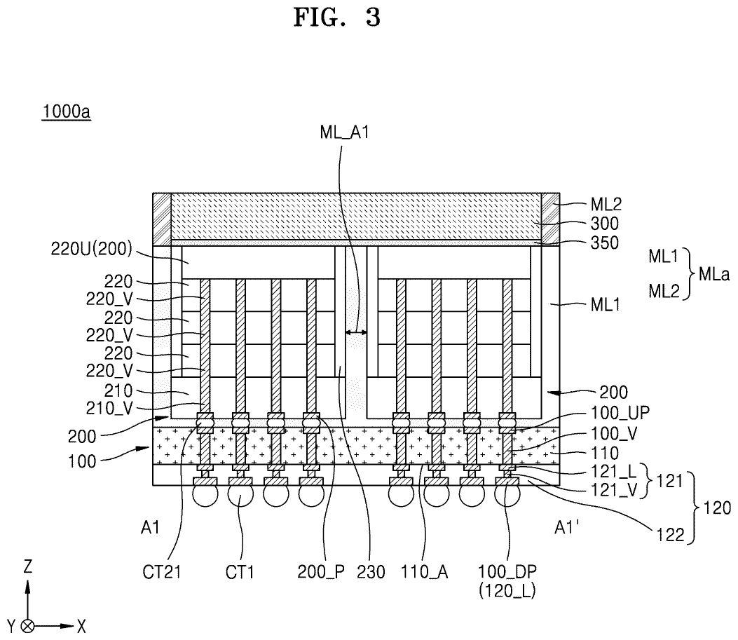

FIG. 3 is a cross-sectional view schematically illustrating a semiconductor package 1000a according to an embodiment.

Most of components constituting the semiconductor package 1000a and materials constituting the components are substantially the same as or similar to those previously described with respect to FIG. 2. Therefore, for convenience of description, differences between the semiconductor package 1000a of FIG. 3 and the semiconductor package 1000 of FIG. 2 will be mainly described below. For example, the descriptions with respect to the embodiment illustrated in FIG. 2 may also be applied to the embodiment illustrated in FIG. 3 unless contexts indicate otherwise.

Referring to FIG. 3, the semiconductor package 1000a may include a semiconductor chip 100, a plurality of stacked structures 200, a stiffener 300, a first adhesive layer 350, and a molding layer MLa.

The molding layer MLa may be located on the semiconductor chip 100 and may surround the plurality of stacked structures 200, the first adhesive layer 350, and the stiffener 300. The molding layer MLa may include an upper molding layer ML2 and a lower molding layer ML1.

The lower molding layer ML1 may be located on the semiconductor chip 100 and may surround the plurality of stacked structures 200. The upper molding layer ML2 may be located on the lower molding layer ML1 and may surround the first adhesive layer 350 and the stiffener 300.

There may be an interface and/or a boundary between the lower molding layer ML1 and the upper molding layer ML2. For example, although constituent materials of the lower molding layer ML1 and the upper molding layer ML2 are the same, there may be an interface and/or a boundary between the lower molding layer ML1 and the upper molding layer ML2. For example, because a curing period of the lower molding layer ML1 is different from that of the upper molding layer ML2, there may be an interface and/or boundary between the lower molding layer ML1 and the upper molding layer ML2. For example, the interface/boundary between the lower molding layer ML1 and the upper molding layer ML2 may be at the same level as a bottom surface of the first adhesive layer 350.

In some embodiments, after mounting the plurality of stacked structures 200 on the semiconductor chip 100, the lower molding layer ML1 may be formed on the semiconductor chip 100 to cover the plurality of stacked structures 200. Thereafter, the lower molding layer ML1 may be removed until the top surface of each of the plurality of stacked structures 200 is exposed. For example, the top surface of each of the plurality of stacked structures 200 may be coplanar with a top surface of the lower molding layer ML1.

Thereafter, the stiffener 300 may be attached onto the plurality of stacked structures 200 through the first adhesive layer 350. Thereafter, the upper molding layer ML2 may be formed on the lower molding layer ML1 to cover the first adhesive layer 350 and the stiffener 300. Thereafter, the upper molding layer ML2 may be polished until the top surface of the stiffener 300 is exposed. For example, a top surface of the upper molding layer ML2 may be coplanar with the top surface of the stiffener 300.

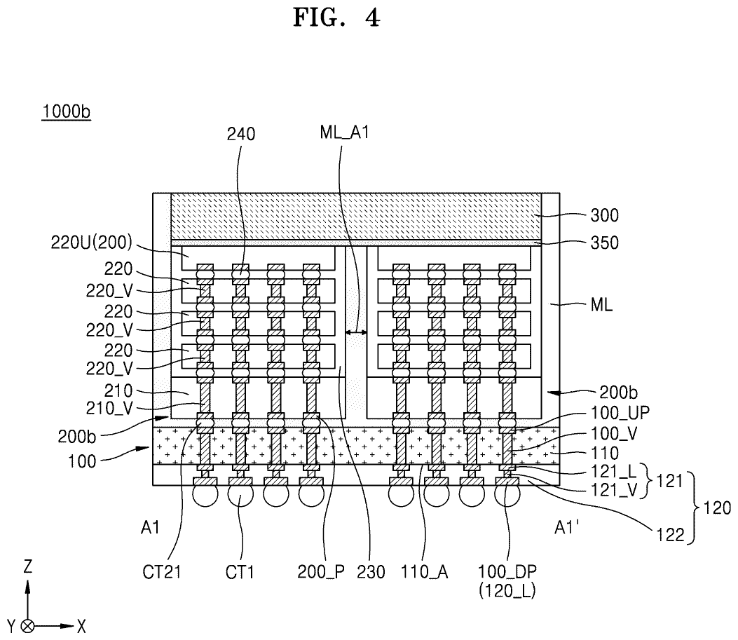

FIG. 4 is a cross-sectional view schematically illustrating a semiconductor package 1000b according to an embodiment.

Most of components constituting the semiconductor package 1000b and materials constituting the components are substantially the same as or similar to those previously described with respect to FIG. 2. Therefore, for convenience of description, differences between the semiconductor package 1000b of FIG. 4 and the semiconductor package 1000 of FIG. 2 will be mainly described below. For example, the descriptions with respect to the embodiment illustrated in FIG. 2 may also be applied to the embodiment illustrated in FIG. 4 unless contexts indicate otherwise.

Referring to FIG. 4, the semiconductor package 1000b may include a semiconductor chip 100, a plurality of stacked structures 200b, a stiffener 300, a first adhesive layer 350, and a molding layer ML.

The plurality of stacked structures 200b may be located on the top surface of the semiconductor chip 100. Each of the plurality of stacked structures 200b may include a buffer chip 210, a plurality of core chips 220, and a core molding layer 230. The buffer chip 210 of each of the plurality of stacked structures 200b may be located at the lowermost end (e.g., under the lowest core chip 220 among the plurality of core chips 220) of each of the plurality of stacked structures 200b, and the plurality of core chips 220 may be stacked on the buffer chip 210 in the vertical direction (Z direction). The core molding layer 230 may be located on the buffer chip 210 and may surround the plurality of core chips 220.

The plurality of core chips 220 may be electrically connected to one another by second connection terminals 240. For example, the second connection terminals 240 may be located between a first core chip and a second core chip adjacent to each other in the vertical direction among the plurality of core chips 220. The first core chip and the second core chip may be electrically connected through the second connection terminals 240 located between upper pads of the first core chip and lower pads of the second core chip. In some embodiments, the second connection terminals 240 may include or may be, for example, solder balls or solder bumps.

Part of the core molding layer 230 may be located between the plurality of core chips 220. For example, the core molding layer 230 may surround the second connection terminals 240 located between the plurality of core chips 220. For example, part of the core molding layer 230 may be located between the first core chip and the second core chip.

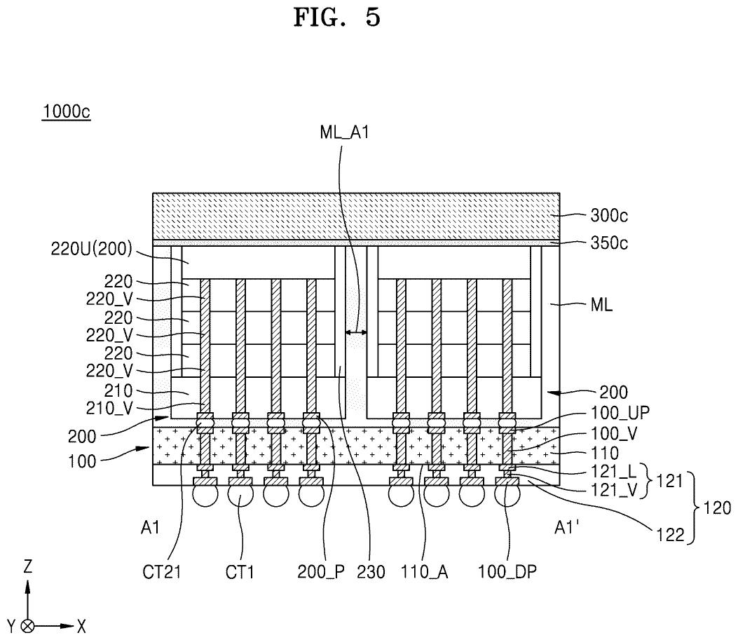

FIG. 5 is a cross-sectional view schematically illustrating a semiconductor package 1000c according to an embodiment.

Most of components constituting the semiconductor package 1000c and materials constituting the components are substantially the same as or similar to those previously described with respect to FIG. 2. Therefore, for convenience of description, differences between the semiconductor package 1000c of FIG. 5 and the semiconductor package 1000 of FIG. 2 will be mainly described below. For example, the descriptions with respect to the embodiment illustrated in FIG. 2 may also be applied to the embodiment illustrated in FIG. 5 unless contexts indicate otherwise.

Referring to FIG. 5, the semiconductor package 1000c may include a semiconductor chip 100, a plurality of stacked structures 200, a stiffener 300c, a first adhesive layer 350c, and a molding layer ML.

The stiffener 300c may be located on the plurality of stacked structures 200. In some embodiments, the stiffener 300c may have a flat plate shape. The first adhesive layer 350c may be located on a bottom surface of the stiffener 300c. The area of a top surface of the first adhesive layer 350c may be the same as that of the bottom surface of the stiffener 300c. For example, the entire area of the top surface of the adhesive layer 350c may be the same as the entire area of the bottom surface of the stiffener 300c. For example, side surfaces of the first adhesive layer 350c may be respectively coplanar with corresponding side surfaces of the stiffener 300c.

The stiffener 300c may cover (e.g., vertically overlap) a top surface of the molding layer ML and top surfaces of the plurality of stacked structures 200. The first adhesive layer 350c may be between the stiffener 300c and the molding layer ML, and between the stiffener 300c and the plurality of stacked structures 200. For example, the first adhesive layer 350c may be conformally formed on the bottom surface of the stiffener 300c.

In some embodiments, the area of a top surface of the stiffener 300c may be the same as that of a top surface of the semiconductor chip 100. For example, the entire area of the top surface of the stiffener 300c may be the same as the entire area of the top surface of the semiconductor chip 100. For example, side surfaces of the stiffener 300c, side surfaces of the first adhesive layer 350c, side surfaces of the molding layer ML, and side surfaces of the semiconductor chip 100 may be respectively coplanar on corresponding side surfaces of the semiconductor package 1000c.

For example, a thermal expansion coefficient of the stiffener 300c may be substantially the same as that of the semiconductor chip 100. For example, a constituent material of the stiffener 300c may be substantially the same as that of a first substrate 110 of the semiconductor chip 100. For example, the stiffener 300c may include the same semiconductor material as the first substrate 110 of the semiconductor chip 100. For example, the stiffener 300c may include Si.

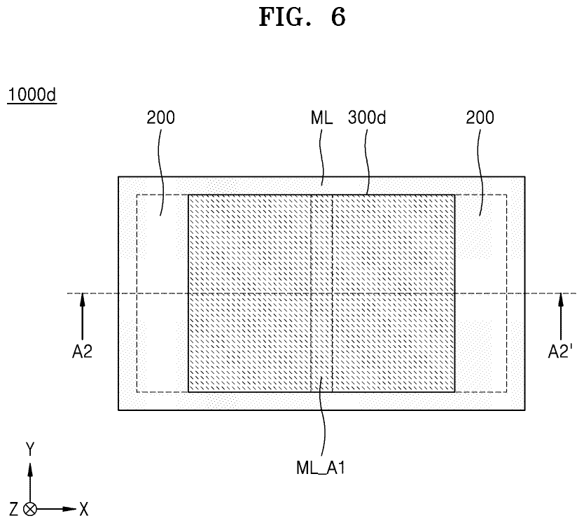

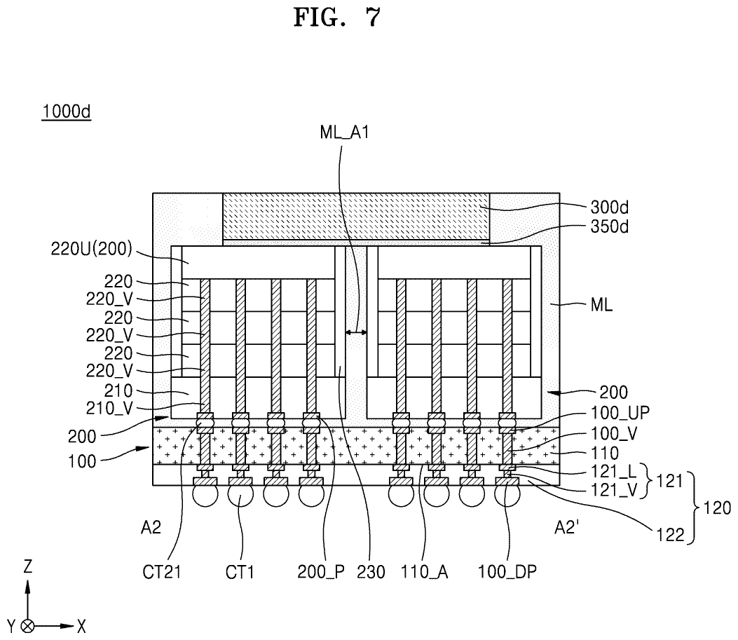

FIG. 6 is a plan view schematically illustrating a semiconductor package 1000d according to an embodiment. FIG. 7 is a cross-sectional view schematically illustrating the semiconductor package 1000d of FIG. 6 taken along line A2-A2′ of FIG. 6.

Most of components constituting the semiconductor package 1000d and materials constituting the components are substantially the same as or similar to those previously described with respect to FIG. 2. Therefore, for convenience of description, differences between the semiconductor package 1000d of FIG. 7 and the semiconductor package 1000 of FIG. 2 will be mainly described below. For example, the descriptions with respect to the embodiment illustrated in FIG. 2 may also be applied to the embodiment illustrated in FIG. 7 unless contexts indicate otherwise.

Referring to FIGS. 6 and 7, the semiconductor package 1000d may include a semiconductor chip 100, a plurality of stacked structures 200, a stiffener 300d, a first adhesive layer 350d, and a molding layer ML.

The stiffener 300d may be located on the plurality of stacked structures 200. In some embodiments, the stiffener 300d may have a flat plate shape. The first adhesive layer 350d may be located on a bottom surface of the stiffener 300d. The area of a top surface of the first adhesive layer 350d may be the same as that of the bottom surface of the stiffener 300d. For example, the entire area of the top surface of the first adhesive layer 350d may be the same as the entire area of the bottom surface of the stiffener 300d. For example, side surfaces of the first adhesive layer 350d may be respectively coplanar with corresponding side surfaces of the stiffener 300d.

For example, the area of the bottom surface of the stiffener 300d may be less than the sum of areas of top surfaces of the plurality of stacked structures 200 and the area of a top surface of a first portion ML_A1 of the molding layer ML. The stiffener 300d may completely cover (e.g., vertically overlap) an upper portion of the first portion ML_A1 of the molding layer ML. For example, the stiffener 300d may cover (e.g., vertically overlap) only part of the top surface of each of the plurality of stacked structures 200. In certain embodiments, the stiffener 300d may not vertically overlap a part of the first portion ML_A1 of the molding layer ML.

Part of the top surface of each of the plurality of stacked structures 200 may contact the first adhesive layer 350d and the remaining part of the top surface of each of the plurality of stacked structures 200 may contact the molding layer ML. The side surfaces of the stiffener 300d may be located on top surfaces of some of the plurality of stacked structures 200. For example, a first side surface of the stiffener 300d and a second side surface of the stiffener 300d opposite the first side surface of the stiffener 300d may be located on different stacked structures among the plurality of stacked structures 200. For example, one or more side surfaces of the stiffener 300d may vertically overlap the top surfaces of the stacked structures 200.

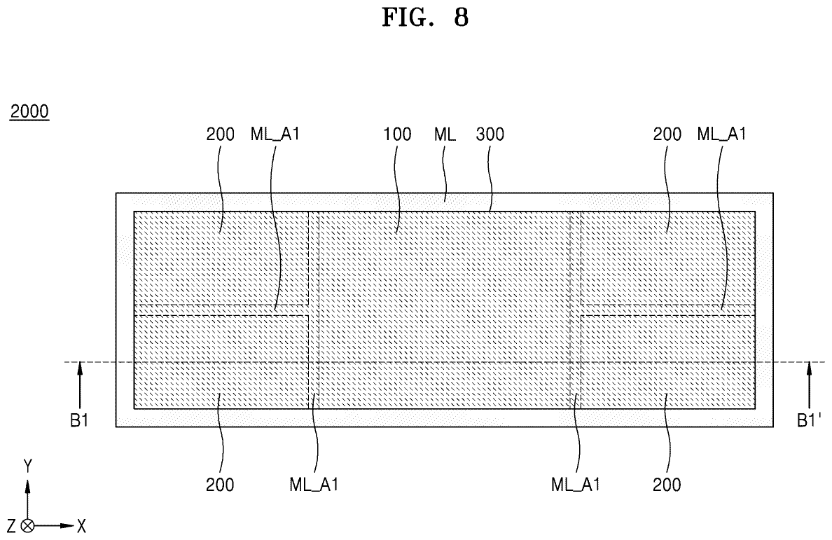

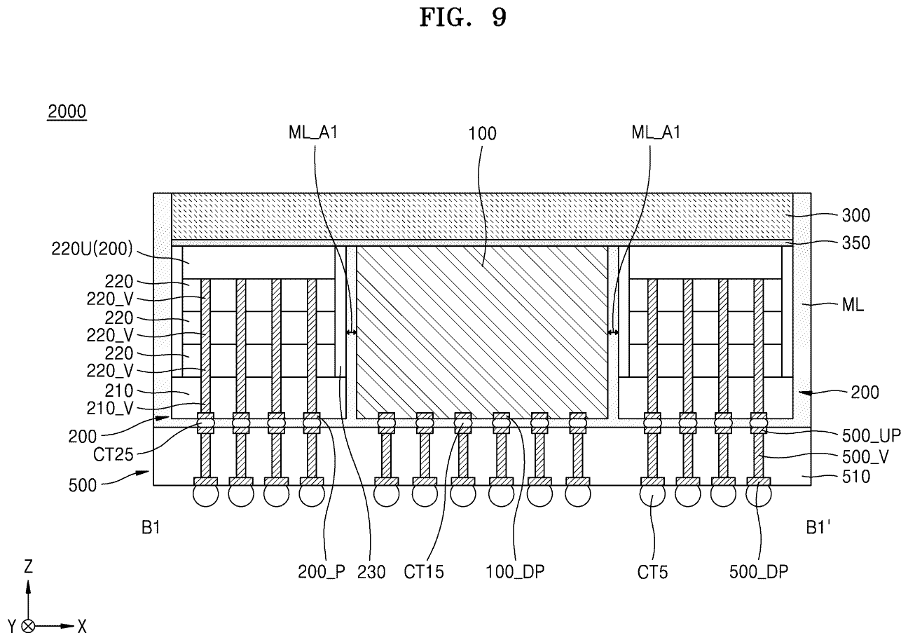

FIG. 8 is a plan view schematically illustrating a semiconductor package 2000 according to an embodiment. FIG. 9 is a cross-sectional view schematically illustrating the semiconductor package 2000 of FIG. 8 taken along line B1-B1′ of FIG. 8.

Most of components constituting the semiconductor package 2000 and materials constituting the components are substantially the same as or similar to those previously described with respect to FIG. 2. Therefore, for convenience of description, differences between the semiconductor package 2000 of FIG. 9 and the semiconductor package 1000 of FIG. 2 will be mainly described below. For example, the descriptions with respect to the embodiment illustrated in FIG. 2 may also be applied to the embodiment illustrated in FIG. 9 unless contexts indicate otherwise.

Referring to FIGS. 8 and 9, the semiconductor package 2000 may include an interposer 500, a semiconductor chip 100, a plurality of stacked structures 200, a stiffener 300, a first adhesive layer 350, and a molding layer ML.

The interposer 500 may include a second substrate 510 and second through vias 500_V passing through the second substrate 510. For example, the interposer 500 may be a glass interposer in which the second substrate 510 includes glass and the second through vias 500_V are through glass vias (TGV). However, the inventive concept is not limited thereto, and the interposer 500 may be a silicon interposer in which the second substrate 510 includes silicon, and the second through vias 500_V are through silicon vias (TSV).

The interposer 500 may further include upper pads 500_UP and lower pads 500_DP. The upper pads 500_UP may be located on a top surface of the second substrate 510 of the interposer 500, and the lower pads 500_DP may be located on a bottom surface of the second substrate 510 of the interposer 500. Each of the upper pads 500_UP and the lower pads 500_DP may be electrically connected to a wiring region of the interposer 500. The upper pads 500_UP may be electrically connected to the lower pads 500_DP by the second through vias 500_V. In some embodiments, a size of the upper pad 500_UP may be less than that of the lower pad 500_DP. For example, the area of the upper pad 500_UP in a plan view may be less than the area of the lower pad 500_DP in a plan view.

External connection terminals CT5 may be attached to the lower pads 500_DP. The external connection terminals CT5 may electrically and physically connect the interposer 500 to an external device on which the interposer 500 is mounted. The external connection terminals CT5 may include or may be, for example, solder balls or solder bumps.

The semiconductor chip 100 and the plurality of stacked structures 200 may be located on the interposer 500. For example, the semiconductor chip 100 may be located in the central region of the interposer 500, and the plurality of stacked structures 200 may be located in an edge region of the interposer 500 to surround the semiconductor chip 100. Although it is illustrated in FIG. 8 that four stacked structures 200 are arranged on the interposer 500, the number of stacked structures 200 arranged on the interposer 500 is not limited thereto.

The semiconductor chip 100 may include a first substrate 110 (refer to FIG. 2) including an active surface 110_A (refer to FIG. 2) and an inactive surface and a first wiring structure 120 (refer to FIG. 2) located on the active surface of the first substrate. In some embodiments, the semiconductor chip 100 may be arranged on the interposer 500 in a face down manner.

The lower pads 100_DP of the semiconductor chip 100 may be electrically connected to the upper pads 500_UP of the interposer 500 through third connection terminals CT15. The lower pads 200_P of the buffer chip 210 of each of the plurality of stacked structures 200 may be electrically connected to the upper pads 500_UP of the interposer 500 through fourth connection terminals CT25. However, methods of electrically connecting the semiconductor chip 100 to the interposer 500 and methods of electrically connecting the plurality of stacked structures 200 to the interposer 500 are not limited thereto.

The semiconductor chip 100 may be spaced apart from the plurality of stacked structures 200 in a horizontal direction (e.g., X-direction). The semiconductor chip 100 and the plurality of stacked structures 200 may transmit/receive signals to/from each other through the interposer 500. A thickness of the semiconductor chip 100 in the vertical direction (Z direction) may be substantially the same as that of each of the plurality of stacked structures 200 in the vertical direction (Z direction).

The molding layer ML may include a first portion ML_A1 located in a space between the semiconductor chip 100 and each of the plurality of stacked structures 200 and a space between the plurality of stacked structures 200. For example, the molding layer ML may fill a space between the semiconductor chip 100 and each of the plurality of stacked structures 200.

The stiffener 300 may be located on the semiconductor chip 100 and the plurality of stacked structures 200. The stiffener 300 may be located on the first portion ML_A1 of the molding layer ML. The stiffener 300 may cover (e.g., vertically overlap) an upper portion of a space between the semiconductor chip 100 and each of the plurality of stacked structures 200.

A thermal expansion coefficient of the stiffener 300 may be substantially the same as that of the interposer 500. Accordingly, a warpage phenomenon, in which the interposer 500 is convexly or concavely bent due to a difference in thermal expansion coefficient between the interposer 500 and the molding layer ML, may be suppressed by the stiffener 300.

The first adhesive layer 350 may be located on a bottom surface of the stiffener 300. The area of a top surface of the first adhesive layer 350 may be the same as that of the bottom surface of the stiffener 300. For example, the first adhesive layer 350 may be located between each of the plurality of stacked structures 200 and the stiffener 300, between the semiconductor chip 100 and the stiffener 300, and between the first portion ML_A1 of the molding layer ML and the stiffener 300.

In some embodiments, the area of the bottom surface of the stiffener 300 may be the same as areas of top surfaces of the plurality of stacked structures 200, the area of a top surface of the semiconductor chip 100, and the area of a top surface of the first portion ML_A1 of the molding layer ML. For example, the stiffener 300 may completely cover (e.g., overlap in a vertical direction) the plurality of stacked structures 200 and the semiconductor chip 100.

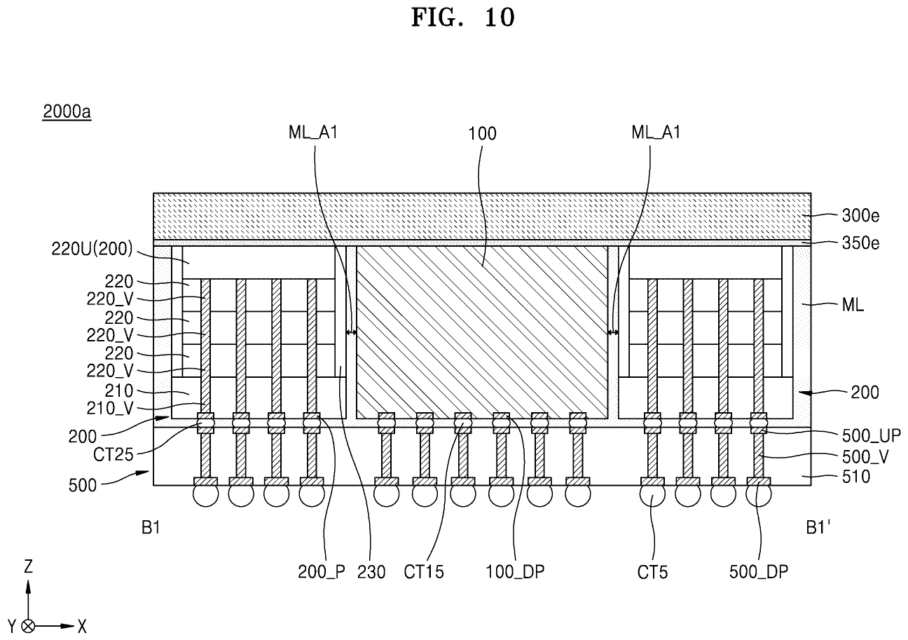

FIG. 10 is a cross-sectional view schematically illustrating a semiconductor package 2000a according to an embodiment.

Most of components constituting the semiconductor package 2000a and materials constituting the components are substantially the same as or similar to those previously described with respect to FIG. 9. Therefore, for convenience of description, differences between the semiconductor package 2000a of FIG. 10 and the semiconductor package 2000 of FIG. 9 will be mainly described below. For example, the descriptions with respect to the embodiment illustrated in FIG. 9 may also be applied to the embodiment illustrated in FIG. 10 unless contexts indicate otherwise.

Referring to FIG. 10, the semiconductor package 2000a may include an interposer 500, a semiconductor chip 100, a plurality of stacked structures 200, a stiffener 300e, a first adhesive layer 350c, and a molding layer ML.

The stiffener 300e may be located on the semiconductor chip 100 and the plurality of stacked structures 200. In some embodiments, the stiffener 300e may have a flat plate shape. The first adhesive layer 350e may be located on a bottom surface of the stiffener 300e. The area of a top surface of the first adhesive layer 350e may be the same as that of the bottom surface of the stiffener 300e. For example, side surfaces of the first adhesive layer 350e may be respectively coplanar with corresponding side surfaces of the stiffener 300e.

The stiffener 300e may cover a top surface of the semiconductor chip 100, a top surface of the molding layer ML, and top surfaces of the plurality of stacked structures 200. The first adhesive layer 350e may be between the stiffener 300e and the semiconductor chip 100, between the stiffener 300e and the molding layer ML, and between the stiffener 300e and the plurality of stacked structures 200. For example, the first adhesive layer 350e may be conformally formed on the bottom surface of the stiffener 300c.

In some embodiments, the area of a top surface of the stiffener 300e may be the same as that of a top surface of the interposer 500. For example, side surfaces of the stiffener 300e, side surfaces of the first adhesive layer 350e, side surfaces of the molding layer ML, and side surfaces of the interposer 500 may be respectively coplanar on corresponding side surfaces of the semiconductor package 2000a.

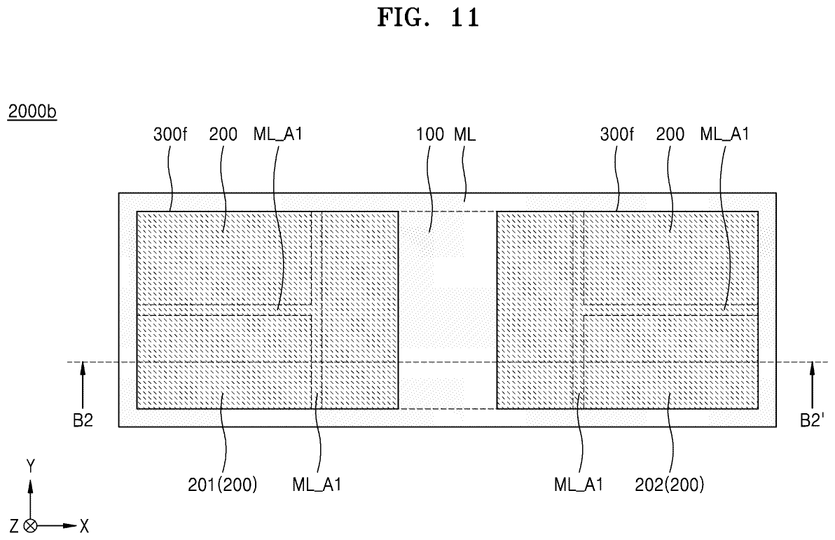

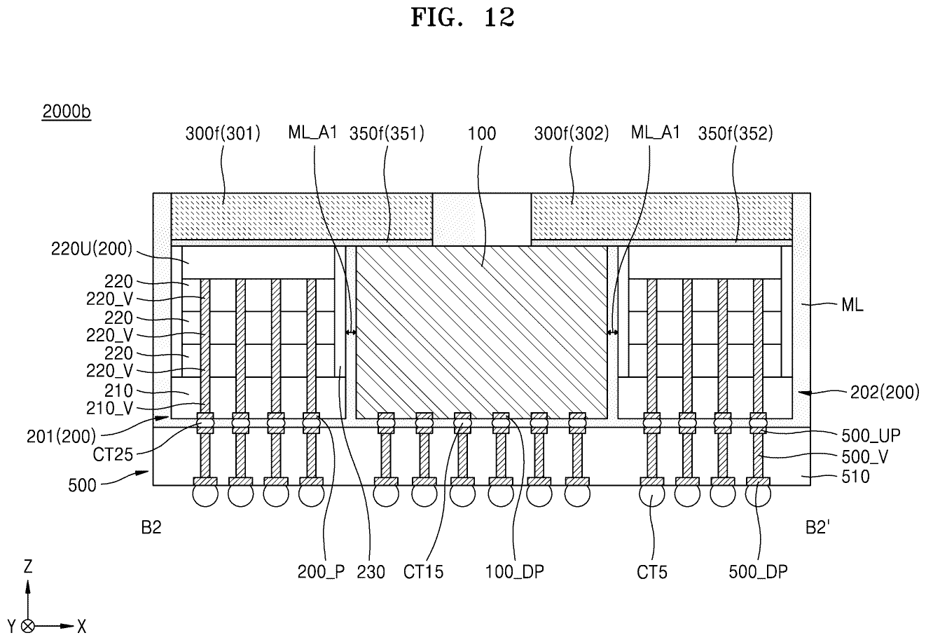

FIG. 11 is a plan view schematically illustrating a semiconductor package 2000b according to an embodiment. FIG. 12 is a cross-sectional view schematically illustrating the semiconductor package 2000b of FIG. 11 taken along line B2-B2′ of FIG. 11.

Most of components constituting the semiconductor package 2000b and materials constituting the components are substantially the same as or similar to those previously described with respect to FIG. 9. Therefore, for convenience of description, differences between the semiconductor package 2000b of FIG. 12 and the semiconductor package 2000 of FIG. 9 will be mainly described below. For example, the descriptions with respect to the embodiment illustrated in FIG. 9 may also be applied to the embodiment illustrated in FIG. 12 unless contexts indicate otherwise.

Referring to FIGS. 11 and 12, the semiconductor package 2000b may include an interposer 500, a semiconductor chip 100, a plurality of stacked structures 200, a plurality of stiffeners 300f, a plurality of adhesive layers 350f, and a molding layer ML.

The plurality of stacked structures 200 may include a first stacked structure 201 and a second stacked structure 202. For example, the first stacked structure 201 and the second stacked structure 202 may be spaced apart from each other with the semiconductor chip 100 therebetween. For example, the first stacked structure 201 and the second stacked structure 202 may be spaced apart from each other in the first horizontal direction (X direction).

The stiffeners 300f may be attached onto the semiconductor chip 100 and the plurality of stacked structures 200. For example, the stiffeners 300f may be attached onto the semiconductor chip 100 and the plurality of stacked structures 200 through the adhesive layers 350f.

The stiffeners 300f may include a first stiffener 301 and a second stiffener 302. The adhesive layers 350f may include a first adhesive layer 351 and a second adhesive layer 352. The first adhesive layer 351 may be located on a bottom surface of the first stiffener 301, and the second adhesive layer 352 may be located on a bottom surface of the second stiffener 302. In some embodiments, the area of a bottom surface of the first adhesive layer 351 may be the same as that of the bottom surface of the first stiffener 301, and the area of a bottom surface of the second adhesive layer 352 may be the same as that of the bottom surface of the second stiffener 302.

Although it is illustrated in FIG. 11 that the stiffeners 300f include two stiffeners 301 and 302, and the adhesive layers 350f include two adhesive layers 351 and 352, the number of stiffeners 300f and the number of adhesive layers 350f are not limited thereto.

The first stiffener 301 may be located on the first stacked structure 201 and the semiconductor chip 100, and the second stiffener 302 may be located on the second stacked structure 202 and the semiconductor chip 100. The first stiffener 301 and the second stiffener 302 may be spaced apart from each other in the first horizontal direction (X direction).

In some embodiments, the first stiffener 301 may be located on (e.g., vertically overlap) a top surface of the stacked structure 200 spaced apart from the first stacked structure 201 in the second horizontal direction (Y direction) among the plurality of stacked structures 200. The second stiffener 302 may be located on (e.g., vertically overlap) a top surface of the stacked structure 200 spaced apart from the second stacked structure 202 in the second horizontal direction (Y direction) among the plurality of stacked structures 200.

Part of the first stiffener 301 may cover an upper portion of a space between the first stacked structure 201 and the semiconductor chip 100. For example, the first stiffener 301 may vertically overlap a space between the first stacked structure 201 and the semiconductor chip 100. Part of the second stiffener 302 may cover an upper portion of a space between the second stacked structure 202 and the semiconductor chip 100. For example, the second stiffener 302 may vertically overlap a space between the second stacked structure 202 and the semiconductor chip 100.

A part of a top surface of the semiconductor chip 100 may contact the first adhesive layer 351, another part of the top surface of the semiconductor chip 100 may contact the second adhesive layer 352, and the remaining part of the top surface of the semiconductor chip 100 may contact the molding layer ML. For example, a first portion ML_A1 of the molding layer ML may be covered with the first stiffener 301 or the second stiffener 302. For example, the area of the bottom surface of each of the first stiffener 301 and the second stiffener 302 may be greater than that of a bottom surface of each of the plurality of stacked structures 200.

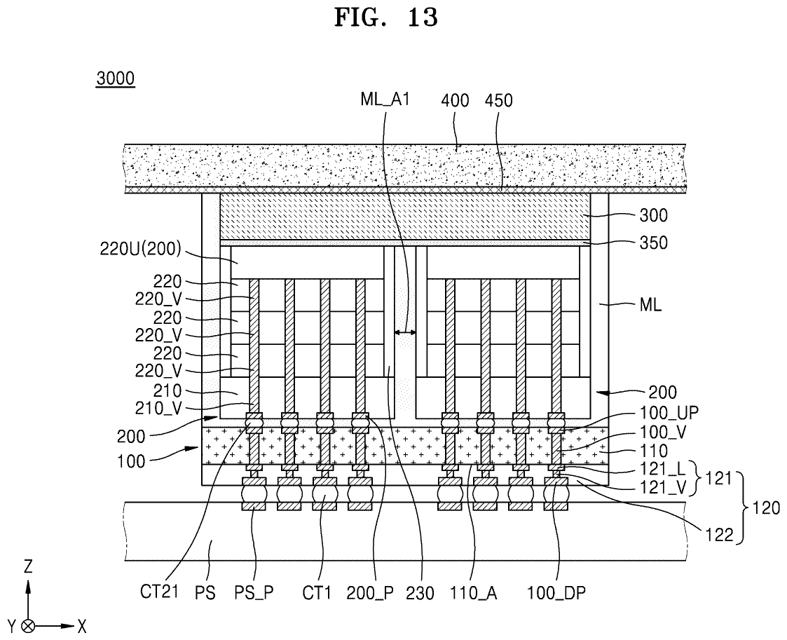

FIG. 13 is a cross-sectional view schematically illustrating a semiconductor package 3000 according to an embodiment.

Most of components constituting the semiconductor package 3000 and materials constituting the components are substantially the same as or similar to those previously described with respect to FIG. 2. Therefore, for convenience of description, differences between the semiconductor package 3000 of FIG. 13 and the semiconductor package 1000 of FIG. 2 will be mainly described below. For example, the descriptions with respect to the embodiment illustrated in FIG. 2 may also be applied to the embodiment illustrated in FIG. 13 unless contexts indicate otherwise.

Referring to FIG. 13, the semiconductor package 3000 may include a package board PS, a semiconductor chip 100, a plurality of stacked structures 200, a stiffener 300, a first adhesive layer 350, a molding layer ML, and a heat dissipation member 400.

In some embodiments, the semiconductor package 3000 of FIG. 13 may be manufactured by mounting one of the semiconductor packages 1000, 1000a, 1000b, 1000c, and 1000d of FIGS. 2 to 7 on the package board PS and then attaching the heat dissipation member 400 on the semiconductor package 1000, 1000a, 1000b, 1000c, or 1000d.

The package board PS may include or may be a printed circuit board PCB including a core insulating layer. The core insulating layer may generally have a flat plate shape or a panel shape. The core insulating layer may include a top and a bottom surfaces opposite to each other, and the top and bottom surfaces of the core insulating layer may be flat.

For example, the core insulating layer may include at least one material selected from prepreg, polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The package board PS may further include upper pads PS_P located on the top surface of the core insulating layer. In some embodiments, the upper pads PS_P may be electrically connected to internal wiring. In some embodiments, the package board PS may further include lower pads located on the bottom surface of the core insulating layer. The lower pads may be electrically connected to the upper pads PS_P by through vias and/or internal wiring. For example, each of the upper pads PS_P and the lower pads may include copper (Cu), nickel (Ni), stainless steel, or beryllium copper.

In some embodiments, the package board PS may include or may be an interposer such as a glass interposer or a silicon interposer.

The semiconductor chip 100 may be located on the package board PS. The semiconductor chip 100 may be electrically connected to the package board PS through external connection terminals CT1. In some embodiments, an active surface 110_A of a first substrate 110 of the semiconductor chip 100 may be arranged on the package board PS to face the package board PS. In some embodiments, the area of a top surface of the semiconductor chip 100 may be less than that of a top surface of the package board PS.

The plurality of stacked structures 200 may be arranged on the semiconductor chip 100. The plurality of stacked structures 200 may be spaced apart from one another in horizontal directions (e.g., X/Y-directions). Each of the plurality of stacked structures 200 may include a buffer chip 210, a plurality of core chips 220 stacked on the buffer chip 210 in the vertical direction (Z direction), and a core molding layer 230 surrounding the plurality of core chips 220 on the buffer chip 210.

The stiffener 300 may be located on the plurality of stacked structures 200. The first adhesive layer 350 may be located on a bottom surface of the stiffener 300 and may completely cover (e.g., overlap in a vertical direction) the bottom surface of the stiffener 300. The stiffener 300 may be attached onto the plurality of stacked structures 200 through the first adhesive layer 350. The molding layer ML may be located on the semiconductor chip 100 and may surround the plurality of stacked structures 200, the first adhesive layer 350, and the stiffener 300. For example, a first portion ML_A1 of the molding layer ML may be located in a space between the plurality of stacked structures 200.

In some embodiments, a thermal expansion coefficient of the stiffener 300 may be substantially the same as that of the semiconductor chip 100. In some embodiments, a constituent material of the stiffener 300 may be the same as that of the semiconductor chip 100. In some embodiments, the stiffener 300 may cover (e.g., vertically overlap) a top surface of the first portion ML_A1 of the molding layer ML. In some embodiments, side surfaces of the molding layer ML may be respectively coplanar with corresponding side surfaces of the semiconductor chip 100. In some embodiments, the uppermost end of the molding layer ML may be coplanar with a top surface of the stiffener 300.

The heat dissipation member 400 may be located on the molding layer ML and the stiffener 300. A second adhesive layer 450 may be located on a bottom surface of the heat dissipation member 400. The area of a top surface of the second adhesive layer 450 may be the same as that of the bottom surface of the heat dissipation member 400. The heat dissipation member 400 may be attached onto the stiffener 300 through the second adhesive layer 450.

In some embodiments, the area of the bottom surface of the heat dissipation member 400 may be greater than that of the top surface of the stiffener 300. For example, the area of a top surface of the heat dissipation member 400 may be the same as that of a top surface of the package board PS.

In some embodiments, the heat dissipation member 400 may include or may be a heat sink such as a heat slug. For example, the heat dissipation member 400 may include a metal-based material, a ceramic-based material, a carbon-based material, or a polymer-based material. The heat dissipation member 400 may be a heat dissipation layer and may have a plate shape, for example, and may therefore be a heat dissipating plate. The second adhesive layer 450 may include a thermal interface material (TIM).

In some embodiments, thermal conductivity of the heat dissipation member 400 may be higher than that of the stiffener 300. In some embodiments, a constituent material of the heat dissipation member 400 may be different from that of the stiffener 300. For example, the semiconductor package 3000 may emit/dissipate heat generated by/from the semiconductor chip 100 and the plurality of stacked structures 200 to the outside through the heat dissipation member 400.

In some embodiments, a constituent material of the first adhesive layer 350 may be different from that of the second adhesive layer 450. For example, the first adhesive layer 350 may include an NCF or a DAF, and the second adhesive layer 450 may include a TIM.

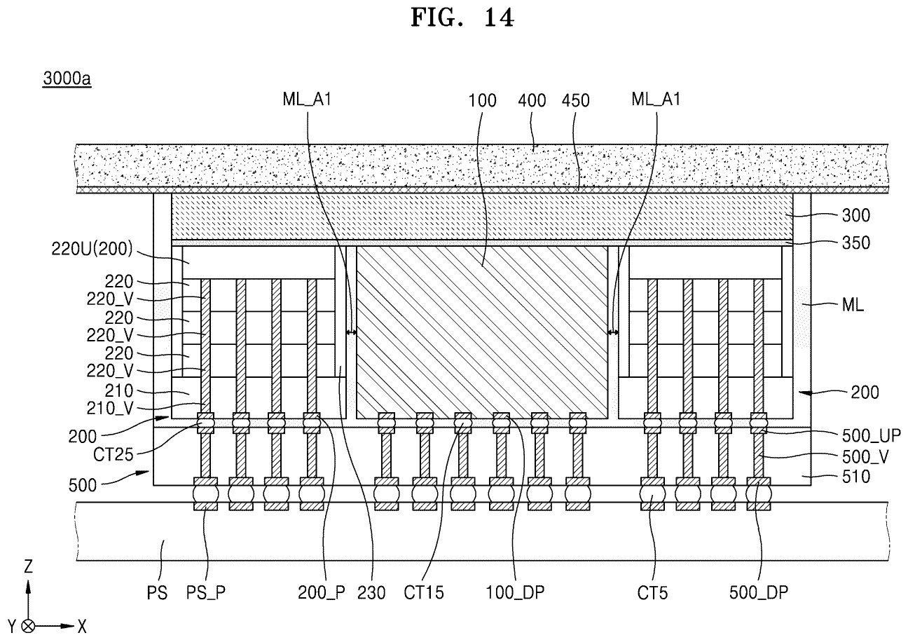

FIG. 14 is a cross-sectional view schematically illustrating a semiconductor package 3000a according to an embodiment.

Most of components constituting the semiconductor package 3000a and materials constituting the components are substantially the same as or similar to those previously described with respect to FIG. 9. Therefore, for convenience of description, differences between the semiconductor package 3000a of FIG. 14 and the semiconductor package 2000 of FIG. 9 will be mainly described below. For example, the descriptions with respect to the embodiment illustrated in FIG. 9 may also be applied to the embodiment illustrated in FIG. 14 unless contexts indicate otherwise.

Referring to FIG. 14, the semiconductor package 3000a may include a package board PS, an interposer 500, a semiconductor chip 100, a plurality of stacked structures 200, a stiffener 300, a first adhesive layer 350, a molding layer ML, and a heat dissipation member 400.

In some embodiments, the semiconductor package 3000a of FIG. 14 may be manufactured by mounting one of the semiconductor packages 2000, 2000a, 2000b, and 2000c of FIGS. 8 to 12 on the package board PS and then attaching the heat dissipation member 400 on the semiconductor package 2000, 2000a, 2000b, or 2000c.

The package board PS may include or may be a printed circuit board PCB including a core insulating layer. The core insulating layer may generally have a flat plate shape or a panel shape. The core insulating layer may include a top and a bottom surfaces opposite to each other, and the top and bottom surfaces of the core insulating layer may be flat. In some embodiments, the package board PS may include or may be an interposer. In some embodiments, the package board PS may be the same as the package board PS of FIG. 13.

The interposer 500 may be located on the package board PS. External connection terminals CT5 may be located between lower pads 500_DP of the interposer 500 and upper pads PS_P of the package board PS. The interposer 500 may be electrically connected to the package board PS through the external connection terminals CT5.

The semiconductor chip 100 and the plurality of stacked structures 200 may be located on the interposer 500. The semiconductor chip 100 may be spaced apart from the plurality of stacked structures 200 in a horizontal direction (e.g., X-direction). The stiffener 300 may be located on the semiconductor chip 100 and the plurality of stacked structures 200. The first adhesive layer 350 may be located on a bottom surface of the stiffener 300. For example, the stiffener 300 may be attached onto the semiconductor chip 100 and the plurality of stacked structures 200 through the first adhesive layer 350. The molding layer ML may be located on the interposer 500 and may surround the semiconductor chip 100, the plurality of stacked structures 200, the first adhesive layer 350, and the stiffener 300.

For example, side surfaces of the molding layer ML may be respectively coplanar with corresponding side surfaces of the interposer 500. For example, the uppermost surface (e.g., a top surface) of the molding layer ML may be coplanar with a top surface of the stiffener 300. For example, a part of the first adhesive layer 350 may be between the stiffener 300 and the molding layer ML.

In some embodiments, a thermal expansion coefficient of the stiffener 300 may be substantially the same as that of the interposer 500. In some embodiments, the area of the stiffener 300 may be less than that of the interposer 500, e.g., in a plan view.

The heat dissipation member 400 may be located on the molding layer ML and the stiffener 300. A second adhesive layer 450 may be located on a bottom surface of the heat dissipation member 400. The area of a top surface of the second adhesive layer 450 may be the same as that of the bottom surface of the heat dissipation member 400. The heat dissipation member 400 may be attached onto the stiffener 300 through the second adhesive layer 450.

In some embodiments, the area of the bottom surface of the heat dissipation member 400 may be greater than that of the top surface of the stiffener 300. For example, the area of a top surface of the heat dissipation member 400 may be the same as that of a top surface of the package board PS.

In some embodiments, the heat dissipation member 400 may include or may be a heat sink such as a heat slug. For example, the heat dissipation member 400 may include a metal-based material, a ceramic-based material, a carbon-based material, or a polymer-based material. The second adhesive layer 450 may include a thermal interface material (TIM).

In some embodiments, thermal conductivity of the heat dissipation member 400 may be higher than that of the stiffener 300. In some embodiments, a constituent material of the heat dissipation member 400 may be different from that of the stiffener 300. For example, the semiconductor package 3000a may emit/dissipate heat generated by/from the semiconductor chip 100 and the plurality of stacked structures 200 to the outside through the heat dissipation member 400.

In some embodiments, a constituent material of the first adhesive layer 350 may be different from that of the second adhesive layer 450. For example, the first adhesive layer 350 may include an NCF or a DAF, and the second adhesive layer 450 may include a TIM.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor package comprising:
a semiconductor chip including a plurality of through vias;
a plurality of stacked structures located on a top surface of the semiconductor chip, each of the plurality of stacked structures including a plurality of core chips stacked in a vertical direction, the plurality of stacked structures spaced apart from one another in a horizontal direction;
a stiffener located on the plurality of stacked structures;
a first adhesive layer located on a bottom surface of the stiffener and including a top surface having the same area as a bottom surface of the stiffener; and
a molding layer located on a top surface of the semiconductor chip and surrounding the plurality of stacked structures, the stiffener, and the first adhesive layer,
wherein a thermal expansion coefficient of the stiffener is the same as that of the semiconductor chip, and
wherein an uppermost surface of the molding layer is coplanar with a top surface of the stiffener.

2. The semiconductor package of claim 1, wherein a part of the stiffener is located on a first portion of the molding layer located in a space between the plurality of stacked structures.

3. The semiconductor package of claim 2, wherein a part of the first adhesive layer is in contact with a top surface of the first portion of the molding layer.

4. The semiconductor package of claim 2, wherein the stiffener completely covers top surfaces of the plurality of stacked structures and the first portion of the molding layer.

5. The semiconductor package of claim 2, wherein a part of a top surface of each of the plurality of stacked structures is in contact with the first adhesive layer, and the rest of the top surface of each of the plurality of stacked structures is in contact with the molding layer.

6. The semiconductor package of claim 1, wherein the first adhesive layer comprises silicon oxide.

7. The semiconductor package of claim 1, wherein the plurality of core chips of each of the plurality of stacked structures have the same thickness in a vertical direction.

8. The semiconductor package of claim 1, wherein a constituent material of the stiffener is the same as that of the semiconductor chip.

9. The semiconductor package of claim 1, further comprising a heat dissipation layer located on the molding layer and the stiffener, wherein thermal conductivity of the heat dissipation layer is higher than that of the stiffener.

10. The semiconductor package of claim 9, wherein the area of a top surface of the heat dissipation layer is greater than that of the stiffener.

11. The semiconductor package of claim 9, further comprising a second adhesive layer located on a bottom surface of the heat dissipation layer and having a top surface with the same area as a bottom surface of the heat dissipation layer,
wherein a constituent material of the first adhesive layer is different from that of the second adhesive layer.

12. The semiconductor package of claim 1, wherein the molding layer comprises a lower molding layer and an upper molding layer located on the lower molding layer,
wherein the lower molding layer surrounds the plurality of stacked structures, and a top surface of the lower molding layer is coplanar with a top surface of each of the plurality of stacked structures,
wherein the upper molding layer surrounds the first adhesive layer and the stiffener, and
wherein there is an interface between the lower molding layer and the upper molding layer.

13. A semiconductor package comprising:
an interposer;
a semiconductor chip located on the interposer;
a plurality of stacked structures located on the interposer, spaced apart from the semiconductor chip in a horizontal direction, and each stacked structure including a plurality of core chips stacked in a vertical direction;
a first stiffener located on the semiconductor chip and the plurality of stacked structures;
a first adhesive layer located on a bottom surface of the first stiffener and including a top surface having the same area as a bottom surface of the first stiffener; and
a molding layer located on the interposer and surrounding the semiconductor chip, the plurality of stacked structures, the first stiffener, and the first adhesive layer,
wherein, the first stiffener covers a first portion of the molding layer located in a space between the plurality of stacked structures and a space between each of the plurality of stacked structures and the semiconductor chip, and
wherein an uppermost surface of the first stiffener is coplanar with a top surface of the molding layer.

14. The semiconductor package of claim 13, wherein the first stiffener completely covers top surfaces of the plurality of stacked structures and a top surface of the semiconductor chip.

15. The semiconductor package of claim 13, further comprising a second stiffener,
wherein the plurality of stacked structures comprises a first stacked structure and a second stacked structure,
wherein the second stacked structure is spaced apart from the first stacked structure in a horizontal direction with the semiconductor chip therebetween,
wherein the first stiffener is located on the first stacked structure and the semiconductor chip and covers a portion of the molding layer located in a space between the first stacked structure and the semiconductor chip, and
wherein the second stiffener is located on the second stacked structure and the semiconductor chip and covers a portion of the molding layer located in a space between the second stacked structure and the semiconductor chip.

16. The semiconductor package of claim 13, wherein a thermal expansion coefficient of the first stiffener is the same as that of the interposer.

17. The semiconductor package of claim 13, wherein the first adhesive layer comprises at least one of a non-conductive film (NCF) and a die attach film (DAF).

18. A semiconductor package comprising:
a package board;
a semiconductor chip located on the package board and including a plurality of through vias;
a plurality of stacked structures located on a top surface of the semiconductor chip, each stacked structure including a plurality of core chips stacked in a vertical direction, and the plurality of stacked structures spaced apart from one another in a horizontal direction;
a stiffener located on the plurality of stacked structures;
a first adhesive layer located on a bottom surface of the stiffener and including a top surface having the same area as a bottom surface of the stiffener;
a molding layer located on a top surface of the semiconductor chip and surrounding the plurality of stacked structures, the stiffener, and the first adhesive layer; and
a heat dissipation layer located on the stiffener and having a top surface wider than a top surface of the semiconductor chip,
wherein, the stiffener covers a first portion of the molding layer located in a space between the plurality of stacked structures,
wherein a thermal expansion coefficient of the stiffener is the same as that of the semiconductor chip,
wherein an uppermost surface of the molding layer is coplanar with a top surface of the stiffener, and
wherein side surfaces of the molding layer are respectively coplanar with corresponding side surfaces of the semiconductor chip.

19. The semiconductor package of claim 18, wherein thermal conductivity of the heat dissipation layer is higher than that of the stiffener.

20. The semiconductor package of claim 18, further comprising a second adhesive layer located between the heat dissipation layer and the stiffener,
wherein the first adhesive layer comprises a non-conductive film (NCF) or a die attach film (DAF), and
wherein the second adhesive layer comprises a thermal interface material (TIM).
